(19) United States
(12) Patent Application Publication
(10) Pub. No.: US 2006/0124939 A1
(43) Pub. Date: Jun. 15, 2006

(54) Method for manufacturing GaN-based light emitting diode using laser lift-off technique and light emitting diode manufactured thereby

(76) Inventors: Jae Seung Lee, Daejeon (KR); Bu Gon Shin, Busan (KR); Min Ho Choi, Pohang-si (KR); Jong Hoon Kang, Seoul (KR); Min A. Yu, Daejeon (KR); Byung Du Oh, Seoul (KR)

Correspondence Address: MCKENNA LONG & ALDRIDGE LLP, 1900 K STREET, NW, WASHINGTON, DC, 20006, US

(21) Appl. No.: 11/175,182

(22) Filed: Jul. 7, 2005

(30) Foreign Application Priority Data
Dec. 13, 2004 (KR) 10-2004-105063

(51) Int. Cl. H01L 21/00; H01L 33/00

(52) U.S. Cl. 257/79; 438/22

(57) ABSTRACT

A simplified manufacturing process for massive production of LEDs that have superior light emitting efficiency and superior heat discharging efficiency. The method employs a laser lift-off technique instead of the flip-chip bonding technique and it does not require a photolithography process, thereby substantially reducing the process steps and enhancing the heat discharging efficiency. The LED chips are formed as unit chips before irradiating the laser, thereby increasing the yield and realizing the mass production by preventing cleavage of the crystal structures. Heat discharging efficiency is also increased by roughening the surface of an n-type GaN layer. The light emitting area can be widened 30% more than in the flip-chip technique. Thus, the present invention serves to increase the light output and the heat discharging area, thereby drastically enhancing the performance of manufacturing high-output LEDs.

### BACKGROUND OF THE INVENTION

1. Field of the Invention

The present invention relates to a method for manufacturing GaN-based light emitting diode (LED), which has superior properties in light emitting efficiency and heat discharging efficiency, in a massive scale by means of a simplified manufacturing process.

The present invention employs a laser lift-off technique instead of the conventional flip-chip technique to simplify the manufacturing process and improve heat discharging efficiency, and provides a solution for preventing cleavage of LED due to irradiation of laser to achieve enhancement of yield and massive production. The present invention also provides a solution for roughening the surface of LED to enhance the light emitting efficiency.

2. Description of the Related Art

LEDs using semiconductor have drawn attention in the field of applied lighting equipment of next generation with its benefits of notably high efficiency in converting electric energy to lighting energy and a long lifespan of more than 5 to 10 years as well as of reducing maintenance costs while decreasing power consumption. However, several problems still remain to be solved before utilizing such LEDs.

The light emitting efficiency of red LEDs commercialized in the late 1960's has exceeded the level of fluorescent lamps upon entering the late 1990's. Blue and green LEDs consisting of GaN-based III-nitride compound semiconductors have succeeded in commercializing in the late 1990's. White LEDs also consisting of GaN-based III-nitrides compound semiconductors are occupying an increasing market share due to a recent success in their commercialization. With the emerge of three primary-colored LEDs as well as white LEDs, their applicability has immersed to various fields, such as back lighting in liquid crystal displays, signal lamps, guiding lamps for airport runways, high beam reading lamps for airplanes or vehicles and lighting lamps, etc. In particular, white LEDs are forecasted to innovate the lighting industry by substituting the existing incandescent lamps and fluorescent lamps. The light emitting efficiency of white LEDs is currently about 25 lm/W, which is only slightly higher than that of the incandescent lamps of about 80 ml/W. With the rapidly enhanced performance, however, its efficiency is expected to exceed that of the fluorescent lamps in the next few years.

Sapphire substrates are generally used for growing the GaN-based III-nitride compound semiconductors to manufacture LEDs. Sapphire substrates are electrically isolated so that the anode and cathode electrodes of LEDs are formed on the front face of wafer.

In general, a low-output GaN-based light emitting diode, as shown in FIG. 1a, is manufactured in a manner of connecting two electrodes 11 and 12 with a top portion thereof after placing the sapphire substrate 10, on which crystal structures have grown, on a lead frame 20. At this time, to improve the heat discharging efficiency, the sapphire substrate is bonded to the lead frame after reducing its thickness to become approximately 100 micron or less.

However, thermal conductivity of sapphire substrates is approximately 27 W/mK. Therefore, even if the thickness is reduced to be about 100 micron, it is difficult to obtain the desired heat discharging properties with the arrangement as shown in FIG. 1a because of the considerably high thermal resistance.

Thus, it is the current trend to mainly employ a flip-chip bonding technique as shown in FIG. 1b to further improve the heat discharging properties of a high output GaN-based light emitting diode. In the flip-chip bonding technique, a chip with an LED structure is bonded to a sub-mount 40, such as a silicon wafer (150 W/mK) having superior thermal conductivity or an AIN ceramic substrate (approximately 180 W/mK), with its inner surface facing out. In FIG. 1b, the drawing reference numeral 10 identifies a sapphire substrate; numerals 11 and 12 identify electrodes; numeral 13 identifies a light emitting layer; numeral 30 identifies a sub-mount; and numeral 40 identifies a flip-chip bonding. Since the heat is emitted through the sub-mount in that case, the heat discharging efficiency is heightened than being emitted through the sapphire substrate. However, the improved rate is not so satisfactory. Furthermore, the flip-chip bonding technique poses another problem of requiring at least 4 to 5 photolithography masks, thereby complicating the manufacturing process.

A new method of manufacturing an LED that has drawn attention recent days in this respect is to employ a laser lift-off technique. Manufacturing an LED by means of the laser lift-off technique is known to generate the most excellent structure for enhancing the heat discharging efficiency by irradiating laser toward a sapphire substrate, on which the LED has grown, and removing the sapphire substrate from the LED's crystal structure before packaging.

Furthermore, unlike the flip-chip bonding technique, the laser lift-off technique does not require a photolithography process, and the steps of manufacturing process are drastically reduced as a consequence. Also, the LED manufactured by the laser lift-off technique has superior properties to that manufactured by the laser lift-off technique because the light emitting area becomes almost equal to the size of chips when employing the laser lift-off technique, while the light emitting area becomes about 60% of the size of chips when employing the flip-chip bonding technique.

Despite the aforementioned advantages, however, the conventional laser lift-off technique poses a problem in massive production of LEDs due to cleavages occurred in their crystal structures upon irradiation of laser. To be specific of the conventional laser lift-off technique, the entire sapphire substrate (e.g., a 2 inch-sized sapphire substrate), on which the crystal structure of LED has grown, is bonded to the sub-mount such as metals or silicon wafer for heat emission, and laser is subsequently irradiated toward a sapphire substrate to remove the same.

However, the conventional technique causes cleavages in the crystal structures of LEDs upon irradiation of laser due to the thermal stress existing between the sapphire substrates and the crystal structures of LEDs. Because of such cleavages, the yield obtained from the conventional laser lift-off technique is considerably decreased in spite of its superior heat discharging efficiency. Hence, this technique is not yet applicable to mass production. Ongoing studies performed by numerous researchers to solve this problem have not yet reached the level of manufacturing LEDs on a massive basis.

### SUMMARY OF THE INVENTION

Accordingly, the present invention provides a method for manufacturing an LED, which has a superior light emitting efficiency as well as a superior heat discharging efficiency, by means of a simplified manufacturing process for its massive production.

The invention is capable of substantially reducing the steps of manufacturing process and enhancing the heat discharging efficiency by employing a laser lift-off technique instead of the flip-chip bonding technique. Also, unlike the conventional laser lift-off technique of forming LED chips as unit chips after irradiating the laser to remove sapphire substrates, on which the LEDs have grown, the present invention forms the LED chips as unit chips before irradiating the laser, thereby increasing the yield and realizing the mass production by preventing cleavage of the crystal structures of LEDs caused due to irradiation of laser. Furthermore, the invention can enhance the heat discharging efficiency by roughening the surface of an n-type GaN layer.

The present invention does not require a photolithography process. As a result, the steps of manufacturing process can be drastically reduced in comparison with the flip-chip bonding technique. Also, the light emitting area can be widened 30% more than in case of employing the flip-chip technique. Thus, the present invention serves to increase the light output as well as the heat discharging area, thereby drastically enhancing the performance of manufacturing high-output LEDs.

### BRIEF DESCRIPTION OF THE DRAWINGS

The accompanying drawings, which are included to provide a further understanding of the invention and are incorporated in and constitute a part of this application, illustrate embodiment(s) of the invention and serve to explain the principle of the invention together with the description. In the drawings:

FIGS. 1a and 1b are views illustrating the structures of a low-output and a high- output GaN-based LEDs, respectively;

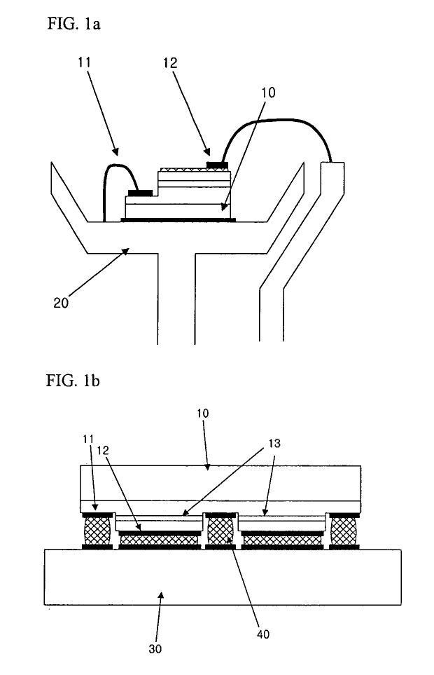

FIGS. 2a and 2b are views illustrating n-type ohmic contact metal patterns relative to a small chip having a single wire bonding and a large chip having four wire bondings, respectively;

FIGS. 3a and 3b are diagrams of electrode wiring lines exemplifying the case of forming n-type ohmic contact metals in which a single wire bonding only is formed in a large chip and the ohmic contact metals are used as electrode wiring lines;

FIG. 4 is a schematic cross-sectional view illustrating a roughened surface structure of an n-type GaN layer;

FIGS. 5a and 5b are schematic cross-sectional views of GaN-based LEDs manufactured by means of the laser lift-off technique according to the present invention adopting a metal substrate and a ceramic or silicon substrate as a sub-mount, respectively.

### DETAILED DESCRIPTION OF THE PREFERRED EMBODIMENT

Wherever possible, the same reference numbers will be used throughout the drawings to refer to the same or like parts.

For purposes of readily understanding the method for manufacturing LEDs by using the lift-off technique in accordance with the present invention, a method of manufacturing high-output LEDs by using the conventional laser lift-off technique will be briefly described in the first place.

As mentioned above, the conventional laser lift-off technique is performed in a manner of bonding the entire sapphire substrate, on which the crystal structure of an LED has grown, to a substrate for heat discharge having a size equivalent to or larger than that of the sapphire substrate, and irradiating laser toward the sapphire substrate so as to remove the same. Each step constituting the entire process is as described below:

(1) Step of Forming a p-type Ohmic Contact

The wafer having a sapphire substrate, on which the crystal structure of an LED has grown, is initially cleaned. Then, the p-type ohmic contact metal is formed on the upper surface of p-type GaN of the wafer by means of vacuum evaporation. Thereafter, thermal treatment is performed to complete the p-type ohmic contact.

(2) Step of Polishing the Surface of a Sapphire Substrate

Next, the sapphire substrate undergoes a polishing treatment. In general, the crystal structure of an LED is grown on the sapphire substrate, which has a thickness of approximately 430 microns. To be processed as a device, the sapphire substrate is thinned to have a thickness of about 80-100microns by means of the lapping/polishing process.

(3) Step of Bonding the Sub-mount Substrate

In case of a high-output LED, a sub-mount substrate is used to increase the heat discharging efficiency. Namely, the polished sapphire substrate is rested on a sub-mount substrate with its inner surface facing out. Then, the metal surface of a p-type ohmic contact of the LED is bonded to the sub-mount substrate by means of a bonding material.

(4) Step of Irradiating the Laser

Thereafter, laser such as excimer is irradiated to remove the sapphire substrate. Here, wavelength of the laser beam is preferably 365 nm or less. The irradiated laser beam passes through the sapphire substrate and is absorbed by gallium nitride (GaN). Consequently, GaN in the interface region between the sapphire and GaN is decomposed to produce metal gallium and nitrogen gas. As a result, the sapphire substrate is debonded from the crystal structure of LED.

The laser irradiating area is commonly less than 1 cm². Therefore, the laser should be movably irradiated within the small area in sequence to debond the entire 2-inch sapphire substrate which is generally used for manufacturing the GaN-based LED.

(5) Step of Forming n-type Ohmic Contact Metal

If required, the n-type GaN surface exposed upon removal of the sapphire substrate then undergoes a polishing treatment or a dry or wet etching treatment so that n-type ohmic contact metal can be evaporated.

(6) Step of Forming a Unit Chip

Thereafter, the sub-mount substrate and the crystal structure of LED are diced into a unit LED chip so as to be attached to a lead frame. Generally, the term “scribing” refers to drawing of lines on a surface of wafer with a diamond tip having a sharp end and excellent strength, while the term “breaking” refers to cutting of the wafer with an impact along the line drawn by means of scribing. Also, the tenn “dicing” refers to cutting of a substrate with a rotating diamond blade. Since the sapphire substrate had already been removed prior to taking this step, the unit chip may be formed by any means of scribing, breaking or dicing treatment.

(7) Step of Treating Wire-bonding and Molding Material

Next, gold wire-bonding is performed to connect the anode with the cathode. The molding material such as epoxy is then covered on the unit chip to complete manufacture of an LED.

In accordance with the steps described above, the sapphire substrate is removed by irradiating laser toward it after bonding the thinner p-type ohmic contact metal of the wafer to the substrate for heat discharge by means of metal having a low melting point such as AuSn. In order to debond the commonly used 2-inch sapphire substrate, the laser should be movably irradiated toward the entire area of the sapphire substrate more than 10 times in sequence, since the area covered by a single irradiation of the laser is 1 cm² or less. At this stage, cleavage is highly likely to occur around the edge of the crystal structure of LED that is covered by a single irradiation of laser. Such cleavage becomes a cause of failing in mass production of LEDs.

Under the circumstances, the inventor of the present invention, who has found a problem that a cleavage occurs in the crystal structure of LED around the edge of wafer in the course of irradiating the laser toward the entire area of sapphire wafer, suggested a measure to solve this problem.

The solution is to form the sapphire substrate as a unit chip before irradiating the laser toward the sapphire substrate, unlike the conventional laser lift-off technique of forming a unit chip after irradiating the laser toward the entire sapphire substrate. Once this method is adapted, no cleavage occurs in the crystal structure of LED at all because a single irradiation of laser beam can separate the sapphire substrate into unit chip areas, each of which is smaller than the area covered by irradiation of the laser beam. Therefore, manufacture of LEDs on a massive basis has now been realized by employing this laser lift-off technique.

The entire process of applying the laser lift-off technique according to the present invention is notably different from the conventional laser lift-off technique mentioned above, particularly in the step (6) of forming a unit chip and the step (4) of irradiating the laser. Also, while the conventional method undergoes only a single step of forming a unit chip, the present invention undergoes two steps in forming a unit chip. Namely, in the case of a high-output LED, the first step is to separate the LED formed on the sapphire substrate into unit chips before laser irradiation, and the second step is to bond the unit chip to a sub-mount substrate and remove the sapphire substrate by means of laser irradiation, and to dice the unit chip bonded to the sub-mount substrate once again. To distinguish the two types of unit chip as described above, the case of including the sapphire substrate will be referred to as a “unit chip,” while the case of bonding to the sub-mount substrate will be referred to as a “unit sub-mount chip.”

The entire process of the present invention will now be described in accordance with the features of each step by omitting the parts overlapped with the above description.

(A) Step of Forming a p-type Ohmic Contact

Ni, Au, Pt, etc. are used as ohmic contact metal, and the metal layers of Ag, Al, Cr, etc. may be additionally used for reflection of light. If necessary, a metal layer may be additionally provided on the top of the p-type ohmic contact metal to improve adhesivity to the sub-mount substrate.

(B) Step of Polishing a Surface of the Sapphire Substrate

Another reason for polishing the sapphire substrate is because a mirror surface is required to allow the laser beam to readily penetrate the sapphire substrate.

(C) Step of Separating the Unit Chip

The most distinctive feature of the present invention discriminated from the prior art lies in performing a step corresponding to the conventional step (6) of forming a unit chip before performing the step (3) of bonding the sub-mount substrate.

In performing the step of separating the unit chip, it is preferable not to undergo the dicing treatment in the presence of the sapphire substrate because the sapphire substrate is so solid that the diamond blade mounted on the dicing equipment is likely to be damaged at a very high speed and that the area of LED can be lost as wide as cut by the blade.

Here, the proximate size of the unit chip to be defined for final manufacture of an LED lamp and not to be lessened in the subsequent process is preferably arranged from 1×1 to 5×5 mm², in case of a high-output LED, and from 0.2 ×0.2 to 1×1 mm², in case of the medium or low-output LED.

Furthermore, the conventional step (6) of forming a unit chip is performed after separating the unit chip by means of laser irradiation. Hence, the unit chip including the sub-mount is separated by means of the scribing/breaking or dicing treatment. On the other hand, formation of the unit chip according to the present invention is conducted before performing the step of bonding the unit chip to the sub-mount substrate as well as before performing the step of separating the sapphire substrate so that the unit chip can be separated by means of the scribing/breaking treatment.

(D) Step of Bonding the Sub-mount Substrate

A material suitable for bonding the sub-mount substrate must be capable of supplying electric current to the LED through itself and readily discharging heat generated from the LED. Thus, the preferable material may be metal such as AuSn, AgSn, PbSn or silver paste, etc. having a low melting point. The sub-mount substrate may comprise materials such as CuW, Si, AlN ceramics, Al₂O₃ ceramics, etc. with its size being equal to or larger than that of the sapphire substrate.

The sapphire wafer, which has become slender by means of the above process, undergoes scribing and breaking treatments so as to be a unit chip. The p-type ohmic contact metal surface of the chip is then bonded to the sub-mount substrate comprising materials such as CuW, Si, AlN ceramics, Al₂O₃ ceramics, etc. The sub-mount substrate has more mass productivity as its size becomes larger than 1 inch. However, the larger the size becomes, thicker thickness is required in order to prevent its breakage or bending in the course of treatment. Thus, increase in thickness is disadvantageous for heat discharge. In consideration of the heat discharging characteristics as well as of mass productivity, it is preferable to select the sub-mount substrate having a size arrangement from about 2 to 5 inches. In the bonding step, a material such as AuSn, AgSn, PbSn or silver paste, etc. that can be adhered at a low temperature of not being higher than 300° C.

When bonded to the sub-mount substrate, the unit chips should be arranged with regular intervals of about hundreds of microns, considering the dicing and wire bonding treatments to be performed for the sub-mount substrate.

(E) Step of Irradiating Laser Beams

In the next step, the sapphire substrate is removed one by one by irradiating laser beams toward the sapphire surfaces of the chips. Since the sapphire substrates are simultaneously removed from one or more chips by a single laser beam irradiation, no cleavage occurs in the crystal structure of a unit chip at all.

(F) Step of Forming n-type Ohmic Contact Metal

The n-type GaN surface exposed upon removal of the sapphire substrate undergoes a polishing or wet/dry etching treatment, if necessary. Then, n-type ohmic contact metal is deposited on the n-type GaN surface. Metal gallium generated at the time of decomposing GaN still exists on the surface of GaN, which has been exposed after removal of the sapphire. The metal gallium layer of such surface lessens the quantity of light emitted from the LED. Hence, the metal gallium layer is removed by means of hydrochloric acid. If necessary thereafter, undoped-GaN layer is etched by means of dry or wet etching treatment so as to expose a n⁺-GaN layer. Metal (e.g., Ti/Al based metal) is then deposited in vacuum to form an n-type ohmic contact.

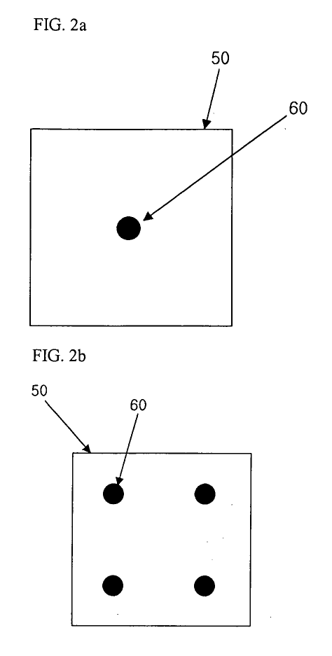

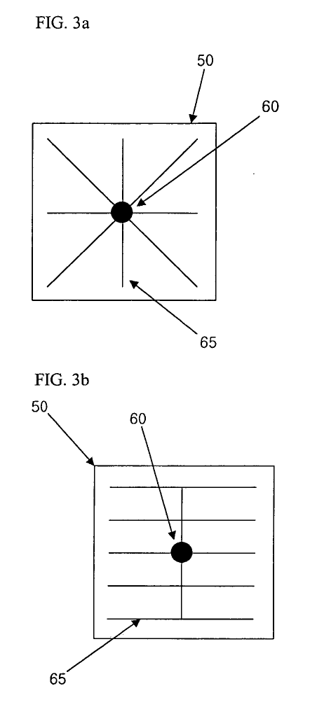

The n-type ohmic contact structure according to the present invention will now be described by reference to FIGS. 2a and 2b. As shown in FIGS. 2a and 2b, the n-type ohmic contact metal can be formed only at a location where Au wire bonding of the LED chip 50 will be performed. Or, as shown in FIGS. 3a and 3b, it is possible to decrease the number of wire bondings by forming the n-type ohmic contact metal 60 at a location where the wire bonding will be performed and by further forming the electrode wiring line 65 in addition. The ohmic contact point is a location, at which gold wire bonding is to be performed in the next step, i.e., a location to be connected to a cathode after performing the gold wire bonding. Therefore, it is different from the ohmic contact wire.

FIG. 2a exemplifies a case, in which an n-type ohmic contact metal 60 is formed in a circular pattern to have a diameter of approximately 100 microns at a center of a small chip sized not more than 0.3×0.3 mm². FIG. 2b exemplifies a case of a larger chip, in which the n-type ohmic contact metal is formed in a circular pattern to have a diameter of about 100 microns in 2×2 array. Depending on the size, the chip may be formed in a circular pattern in 2×2 array or in 3×3 array.

FIGS. 3a and 3b show examples of electrode wiring lines to form a single Au wiring bonding only. The n-type ohmic contact metal is formed in the shape of electrode wiring lines in various types having a width of about tens of microns. One wire bonding may be performed at the center thereof. Or, if necessary, two or more wire bondings may be performed.

As described above, the n-type ohmic contact metal according to the invention is not intended to embody a fine line width having a micrometer unit. Hence, it is sufficiently possible to embody the n-ohmic contact metal by means of a shadow mask without undergoing a photolithography process. Thus, the method of manufacturing the LED according to the present invention does not require any complicated photolithography process. If an embodiment of the fine line width having a micrometer unit is required, the photolithography process may be carried out. In other words, if the width of lead wire is greater than 50 microns, the shadow masking process is sufficient. The photolithography process is required only when the width of lead wire is less than 50 microns. However, the thicker the width of lead wire is, the more the emitting light is hidden, thereby lessening the quantity of light emission.

(G) Step of Roughening The Surface of n-type GaN Layer

Roughening the surface of n-type GaN layer according to the invention will nextly be described. In general, there are two approaches to enhance the light emitting efficiency of LED.

The first is to increase an internal quantum efficiency, and the second is to increase a light extracting efficiency. The first approach of increasing the internal quantum efficiency is related to the quality of crystal structure of LED as well as to the structure of quantum well. Although the structure embodying a high internal quantum efficiency has already been known, diverse researches are still in progress in that respect. However, this approach has not yet brought any additional improvements. On the other hand, the second approach of increasing the light extracting efficiency is to allow the light generated from the light emitting layer to be emitted outward as much as possible. This approach still has many rooms for improvement.

Since the refractive index of the GaN layer is generally about 2.5, a total reflection angle or a light escaping angle is approximately 37 degrees in relation to the refractive index 1.5 of epoxy, which is a molding material. In other words, the light incident to the interface of epoxy with an angle greater than 37 degrees from the light emitting layer cannot escape outward but is shut inside by continuously repeating the total reflection on the interface of light emitting layer. The light incident with an angle less than 37 degrees only can escape outward. If ignoring the light generated from the side or rear surface of the light emitting layer, only about 10% of light is expected to successfully escape outward from the light emitting layer. Accordingly, the surface of the n-type of GaN layer is roughened by increasing the total reflection angle so that a large quantity of light can be escaped.

In order to extract the light of better quality, the method according to the invention comprises a step of removing the sapphire substrate by means of laser and a step of roughening the surface of the n-type of GaN layer exposed before or after forming the electrode wiring lines.

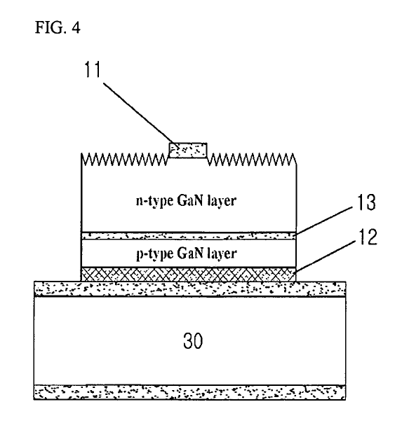

FIG. 4 shows a structure of LED having an n-type GaN layer with a roughened surface. As explained in greater detail with reference to FIG. 4, if the surface of the n-type GaN layer is exposed upon removal of a sapphire substrate by means of laser, the surface can be roughened to have a shape of polygonized cone thereon by means of dry or wet etching treament before or after forming the n-type ohmic contact metal. The step of roughening the surface of the n-type GaN layer preferably precedes the step of forming the n-type ohmic contact metal, though it may follow the same. The wet etching treatment is performed by melting KOH into distilled water until its concentration reaches about 2 or less mole (0.1-2 mole) and by irradiating an UV light source after putting samples into the distilled water. On the other hand, the dry etching treatment is performed by means of a plasma etching technique, which uses gas such as Cl₂, BCl₃, etc. The area, in which the n-type ohmic contact metal of the n-type GaN layer has not been formed, is coated with a thickness less than a few microns after mixing a material, e.g., TiO₂ powder having a refractive index of about 2.4, which is transparent under the visible light having a refractive index similar to that of GaN, with epoxy so as to induce an effect similar to the roughening of the surface and to finalize the process by packing the molding material.

In particular, in case of the dry etching treatment, it is preferable to etch a portion, which will become a edge of the unit chip, until the n-type GaN layer is exposed through the p-type GaN and the light emitting layer. After scribing and breaking treatments have been performed to form the unit chip, numerous cleavages occur on the edges of the broken unit chip. Upon operating the device, since the reliability of the device deteriorates when a leakage current flows through the cleavages, it is preferable to etch the p-type GaN and the light emitting layer so as to break the leakage current.

(H) Step of Dicing the Unit Sub-mount Chip

After forming the n-type ohmic contact metal layer as illustrated in FIGS. 2a to 3b, the sub-mount substrate is cut into a unit chip by means of dicing treatment, etc. Then, the unit chip is bonded to the lead frame.

(I) Step of Wire Bonding and Treatment of Molding Materials

Next, wire bonding is performed for electric connection of anode and cathode. Thereafter, epoxy molding is performed to complete manufacture of the LED.

Although the forgoing description exemplified the case of high-output LED, the invention may be applicable to the case of low-output LED. The latter is accomplished by performing the steps of: forming a p-type ohmic contact upon the p-type GaN-based semiconductor layer having the LED structure; polishing the surface of the sapphire substrate of the sapphire wafer; separating the sapphire substrate, on which the LED has grown as a unit chip, into a unit chip; bonding the p-type ohmic contact metal surface separated as a unit chip to the lead frame; irradiating the laser to the surface of the sapphire substrate of the unit chip bonded to the lead frame so as to remove the sapphire substrate; performing wire bonding and a treatment of molding materials on the unit chip, from which the sapphire substrate has been removed.

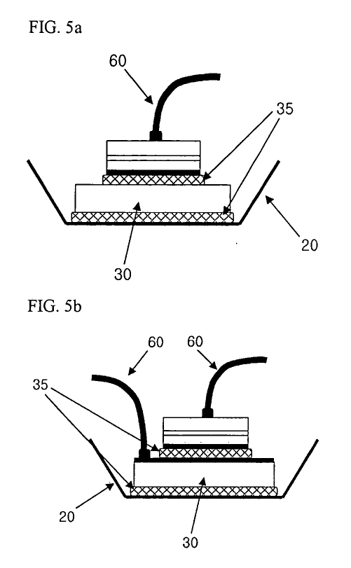

The structure of LED manufactured by the method according to the present invention will now be described with reference to FIG. 5a. FIG. 5a is a schematic cross-sectional view of LED manufactured by means of the laser lift-off technique employing a metal substrate as a sub-mount 30. Here, the metal sub-mount is spontaneously connected to the anode. Therefore, Au wire bonding 60 is connected to the cathode only. On the other hand, FIG. 5b is a schematic cross-sectional view of the LED manufactured by means of the laser lift-off technique employing a ceramic substrate, such as a silicon wafer or AlN, as a sub-mount 30. Since the sub-mount has insufficient conductivity here, two Au wire bondings 60 are required for connection of the anode with the cathode.

In the forgoing manufacturing process, manufacture of the LED may be accomplished with a simpler manner than omitting some of those steps. The Au wire may be directly bonded to the exposed surface of the n-type GaN layer by means of the laser lift-off technique and by omitting the step of forming the n-type ohmic contact metal in the above process. At this time, a contact resistance increases more than in the case of using the n-type ohmic contact metal. However, it does not greatly affect the operation of the low-output LED. In that case, the sub-mount such as metal or ceramics, etc. is not required either. In the step preceding the laser lift-off of the sapphire substrate, the Au wire bonding process may be performed after directly bonding the unit LED chip to the lead frame and removing the sapphire substrate. At this time, the anode is connected to a bottom surface of the lead frame.

Employing the manufacturing process of performing the scribing and breaking treatment on the sapphire wafer, on which the crystal structure of the LED has grown, to make the sapphire wafer a unit chip, and removing the sapphire substrate with the laser thereafter, the sapphire substrate can be removed by a single irradiation of the laser beam in the structure of LED of a unit chip. Thus, the reduction of yield due to cleavage of the crystal structure of LED can be completely eliminated in comparison with the prior art.

Also, if the GaN based LED is manufactured according to the present invention, no photomask is required at all, unlike the conventional flip-chip LED (the flip-chip technique requires more than 3 sheets of photomask). Therefore, the manufacturing process is drastically simplified. Furthermore, no edge area is required for scribing/breaking treatment because of non-existence of a pattern. Accordingly, the light emitting area of the LED can be enlarged 30% or greater compared to the flip-chip structure. Thus, the light output can be enhanced, and the heat discharging area can be notably increased as well. Consequently, the performance can be substantially enhanced in manufacture of high-output LED, in particular. With regard to the heat discharging area, the heat can be discharged toward the entire area in case of the laser lift-off technique. In case of the flip-chip technique, however, the heat is discharged toward the flip-chip bonded area only. Since the flip-chip bonded area depends on its layout, exact value cannot be defined. It usually does not exceed 50% of the chip area.

In summary, compared with the manufacturing process for LED according to the conventional lift-off technique, the present invention is capable of completely eliminating cleavage of the crystal structure of LED caused at the time of laser lift-off, which is a reason for failure in commercialization under the conventional art. Therefore, the yield in the laser lift-off process reaches almost 100%. As a result, mass production of GaN based LEDs having superior heat discharging efficiency with large light discharging area and high reliability, etc. can be accomplished.

The forgoing embodiments are merely exemplary and are not to be construed as limiting the present invention. The present teachings can be readily applied to other types of methods. The description of the present invention is intended to be illustrative, and not to limit the scope of the claims. Many alternatives, modifications, and variations will be apparent to those skilled in the art.

1. A method for manufacturing a light emitting diode using a sapphire substrate, on which a crystal structure of the light emitting diode has grown, comprising the steps of:
separating the sapphire substrate, on which said light emitting diode has grown, into a unit chip; and
irradiating laser toward said sapphire substrate separated into said unit chip to remove the sapphire substrate.

2. The method as claimed in claim 1, wherein said unit chip has a size arranged from 0.2×0.2 to 5×5 mm².

3. A method for manufacturing a light emitting diode using a sapphire substrate, on which a crystal structure of the light emitting diode has grown, comprising the steps of:
forming a p-type ohmic contact on a p-type GaN based semiconductor layer, which is the top layer of a structure of said light emitting diode;
polishing the sapphire substrate surface of said sapphire wafer;
separating the sapphire substrate, on which said light emitting diode has grown, into a unit chip;
bonding said p-type ohmic contact metal surface separated into said unit chip to a sub-mount substrate;
irradiating laser toward the surface of said unit chip substrate bonded to said sub-mount substrate to remove the sapphire substrate;
forming an n-type ohmic contact on an n-type GaN based semiconductor layer having a structure of light emitting diode exposed upon removal of said sapphire substrate, and dicing the sub-mount substrate, on which said unit light emitting diode chip has been attached as a unit sub-mount chip;
attaching the unit sub-mount chip, on which the structure of said unit light emitting diode has been bonded, to a lead frame; and
wire bonding an anode and a cathode of the unit sub-mount chip, on which the structure of said unit light emitting diode has been bonded to the lead frame, and performing a treatment of molding materials.

4. A method for manufacturing a light emitting diode using a sapphire substrate, on which a crystal structure of the light emitting diode has grown, comprising the steps of:
forming a p-type ohmic contact on a p-type GaN based semiconductor layer of a structure of said light emitting diode;
polishing the sapphire substrate surface of said sapphire wafer;
separating the sapphire substrate, on which said light emitting diode has grown, into a unit chip;
attaching said p-type ohmic contact metal surface separated into said unit chip to a lead frame;
irradiating laser to the sapphire substrate surface of unit chip attached to said lead frame to remove the sapphire substrate; and
wire bonding and treating molding materials on said unit chip, from which said sapphire substrate has been removed.

5. The method as claimed in claim 3, wherein the surface of n-type GaN based semiconductor layer exposed upon removal of said sapphire substrate is roughened by means of a wet etching or a dry etching treatment.

6. The method as claimed in claim 3, wherein an effect of roughening the surface is induced by coating the surface of said n-type GaN based semiconductor layer with a material having a refractive index similar to that of said n-type GaN based semiconductor layer and transparent under the visible light through mixture with the molding materials, and coating said surface once again with the molding materials only.

7. The method as claimed in claim 6, wherein said material having a refractive index similar to that of said n-type GaN based semiconductor layer and transparent under the visible light is TiO₂ powder.

8. The method as claimed in claim 3, wherein said n-type ohmic contact is formed by one ore more ohmic contact points or a combination of one ore more ohmic contact points with ohmic contact wire lines.

9. The method as claimed in claim 3, wherein said sub-mount substrate comprises conductive or non-conductive materials.

10. The method as claimed in claim 9, wherein, if said sub-mount substrate comprises conductive materials, said p-type electrode wire bonding may be unperformed by allowing said sub-mount substrate to additionally serve the function of said p-type electrode.

11. The method as claimed in claim 3, wherein said sub-mount substrate comprises at least one of materials selected from a group consisting of CuW, Si, AlN cerimic, and Al₂O₃.

12. The method as claimed in claim 3, wherein a bonding material comprising at least one selected from a group consisting of AuSn, AgSn, PbSn, Sn, and silver paste is used to bond said p-type ohmic contact metal surface with said sub-mount substrate.

13. A light emitting diode manufactured by any one of claims 1, 3, and 4.
